(19) United States
(12) Patent Application Publication
(10) Pub. No.: US 2022/0063052 A1
(43) Pub. Date: Mar. 3, 2022

(54) SURFACE PLATE FOR POLISHING DEVICE, AND POLISHING DEVICE AND POLISHING METHOD

(71) Applicant: MARUISHI SANGYO CO., LTD., TOKYO (JP)

(72) Inventors: MATSUO IIDA, TOKYO (JP); TOSHIYASU YAJIMA, TOKYO (JP); DAISUKE NINOMIYA, TOKYO (JP); SHIMPEI TATSUNO, TOKYO (JP)

(73) Assignee: MARUISHI SANGYO CO., LTD., TOKYO (JP)

(21) Appl. No.: 17/424,261

(22) PCT Filed: Mar. 2, 2020
(86) PCT No.: PCT/JP2020/008613

§ 371 Date: Jul. 20, 2021

(30) Foreign Application Priority Data
Mar. 20, 2019 (JP) P2019-052081

(51) Int. Cl. B24B 37/14

(52) U.S. Cl. CPC B24B 37/14

(57) ABSTRACT

The present invention relates to improvement of a surface plate to be used in a polishing apparatus, with a polishing pad to be attached on the surface plate. The surface plate of the present invention includes: a surface plate body; and a release layer including a release film or release paper formed on a surface of the surface plate body on which the polishing pad is to be attached. The release layer has a peel force of a surface thereof of 0.08 N/50 mm or more and 5.0 N/50 mm or less. The present invention can be suitably used in a polishing apparatus utilizing a general polishing pad including a pressure-sensitive adhesive. The present invention allows polishing pad fixing work and replacement work to be performed more easily than in a conventional technique.

### TECHNICAL FIELD

The present invention relates to a surface plate (platen) for a polishing apparatus used in a polishing step for a semiconductor wafer and the like to be used in a semiconductor component, an electronic component and the like. Specifically, the present invention relates to a surface plate on which a polishing pad is attached in a polishing step, and in which the polishing pad can be efficiently replaced.

### BACKGROUND ART

In a process of producing a semiconductor component or an electronic component such as a semiconductor wafer, a glass substrate for a display or a substrate for a hard disc, a polishing step for flattening or mirror-finishing a substrate surface is generally incorporated. FIG. 1 is a diagram roughly illustrating a general polishing apparatus (one-surface polishing apparatus) and a polishing step performed with the same. In the polishing step, after a polishing pad is fixed in the polishing apparatus, a work (member to be polished) such as a wafer is pressed against the polishing pad, and polished by relatively sliding them with a polishing slurry supplied.

In fixing the polishing pad, a pressure-sensitive adhesive such as a pressure-sensitive adhesive tape is precedently bonded to the polishing pad, and the polishing pad is attached to a surface plate of the polishing apparatus via the pressure-sensitive adhesive (FIG. 1). A portion of the surface plate on which the polishing pad is attached is sometimes referred to as a surface plate body or a platen.

The method of fixing a polishing pad with a pressure-sensitive adhesive has been a factor of largely deteriorating working efficiency in the polishing step because polishing pad replacement work requires much time and labor. Specifically, it is necessary, in the polishing pad replacement, to separate the used polishing pad from the surface plate, and at this point, a portion of the pressure-sensitive adhesive sometimes remain on the surface plate. It is necessary to perform, before fixing a new polishing pad, a step of removing and cleaning the pressure-sensitive adhesive remaining on the surface plate with a solvent or the like, which makes the replacement work troublesome.

The applicant of the present application has proposed, against the conventional method of fixing a polishing pad with a pressure-sensitive adhesive, a polishing pad using a specific adsorbent and a fixation method using the same (Patent Document 1). This polishing pad includes, on a surface to be attached to a surface plate, an adsorbent containing a silicone composition having a specific configuration. As the name suggests, the adsorbent here is intended to fix the polishing pad to the surface plate by the adsorption action, and does not allow a residual material to remain after separation from the surface plate. Further, since the polishing pad can be attached again after being separated from the surface plate, it can be smoothly fixed again, so that the polishing pad replacement work can be efficiently performed. Thus, the polishing work can be improved in efficiency.

### RELATED ART DOCUMENT

### Patent Document

Patent Document 1: Japanese Utility Model Registration No. 3166396

### SUMMARY OF THE INVENTION

### Problems to be Solved by the Invention

The above-described polishing pad provided with the adsorbent is definitely useful, and is expected to be widely spread. Under present circumstances, however, conventional polishing pads including a pressure-sensitive adhesive are used still in a large number of cases. Therefore, the present applicant presumed that handleability improvement of a conventional polishing pad equipped with a pressure-sensitive adhesive should be considered while the use of the polishing pad equipped with the adsorbent is being encouraged.

The present invention was accomplished under these circumstances, and discloses the configuration of a polishing apparatus capable of easing polishing pad fixation work and replacement work in a polishing step where a polishing pad including a surface-pressure adhesive is used as compared with those performed in a conventional process.

### Means for Solving the Problems

Even though there is a problem factor in working efficiency in a polishing pad including a pressure-sensitive adhesive, improvement of the configuration of the polishing pad is not necessarily a priority matter. Even if the problem can be solved by improving the polishing pad including a pressure-sensitive adhesive, it cannot be easily widely spread. This can be predicted also from the case of the polishing pad including an adsorbent proposed by the present applicant.

Further, even though the problem to be solved by the present invention is to make a polishing pad easily fixed and easily replaced, it is not preferable to focus merely on this problem. Even when handleability in replacement work and the like is improved, such an improvement as obstructing polishing work, which is an essential object of a polishing apparatus, should be avoided.

As a result of studies made in consideration of the above-described circumstances, the present inventors focused on the configuration of a surface plate of a polishing apparatus. Thus, it was found that a surface plate provided with a comparatively simple configuration can improve efficiency of polishing pad replacement work with the quality of polishing work retained, resulting in achieving the present invention.

Specifically, the present invention provides a surface plate for a polishing apparatus, to be used in a polishing apparatus, with a polishing pad attached thereon, including a surface plate body, and a release layer including a release film or release paper formed on a surface of the surface plate body on which the polishing pad is to be attached, and the release layer has a peel force of the surface thereof of 0.08 N/50 mm or more and 5.0 N/50 mm or less.

As described above, the present invention provides the surface plate for a polishing apparatus provided with the release layer formed from a release film or release paper on the surface of the surface plate body. In the present invention, polishing work is performed with a polishing pad fixed on the surface plate via the release layer. Now, the surface plate of the present invention, and a polishing apparatus and a polishing method to which the surface plate is applied will be described.

### (I) Surface Plate including Release Layer of Present Invention

In the surface plate of the present invention, the release film or the release paper forming the release layer is a generic term for a film or paper obtained by subjecting a resin film substrate or a paper substrate to a release treatment for developing peeling action on the surface thereof. The peeling action here refers to action to fix various adhesives, paint coating films and the like in a peelable state without adhesion. Such a release film or release paper is stacked on a pressure-sensitive adhesive layer of commercially available pressure-sensitive adhesive tapes, stickers, adhesive plasters, poultices to be applied to the skin, and the like.

In the present invention, the release layer including a release film or release paper having a specific peel force against the surface of a surface plate is formed. The peel force of the release layer is thus prescribed for optimizing both efficiency improvement of polishing pad replacement, and workability and polish quality attained in polishing work. Specifically, when the release layer has a peel force over 5.0 N/50 mm, an adhesive force of a pressure-sensitive adhesive of a polishing pad is so strong that the efficiency of polishing pad replacement will deteriorate. On the other hand, or more when the peel force is less than 0.08 N/50 mm, fixation of the polishing pad on the surface plate is so weak that the polishing pad may be shifted or peeled during the polishing work. Further, even if the polishing pad is not definitely shifted, behavior of a polishing surface of the polishing pad may become unstable, which may cause a scratch or waviness/distortion on the surface of a work. For these reasons, a release film or release paper prescribed in the peel force is applied.

The peel force refers to a force necessary for peeling a pressure-sensitive adhesive attached to the release film or the release paper. As a specific index adopted in the present invention, a value measured, with a tensile tester, when a specific pressure-sensitive adhesive tape (“No. 31 B” (50 mm width) manufactured by Nitto Denko Corporation) is attached to a surface of a release layer of a film or the like, is allowed to stand still at room temperature for 2 hours, and is peeled at a peeling angle against the film or the like of 180° and a peeling speed of 300 mm/min.

As described above, the release film or the release paper is a material formed by applying a release agent to a resin film substrate or a paper substrate. Examples of the release agent include a silicone-based resin, a fluorine-based resin, a long-chain alkyl-based resin, a paraffin-based resin, and an olefin-based resin. These resins can exhibit the above-described appropriate peel force against the pressure-sensitive adhesive of the polishing pad as well as allows merely a small amount of the pressure-sensitive adhesive to remain. The surface of the release layer of the surface plate of the present invention preferably includes any of these resins. A specific composition of the release agent can be, as the silicone-based resin, a homopolymer of an organopolysiloxane compound, a covalent polymer resulting from radical polymerization of an organopolysiloxane compound and a radical polymerizable monomer, or the like. The long-chain alkyl-based resin can be a long-chain alkyl pendant type polymer (such as Pyroyl 1010 (manufactured by Lion Specialty Chemicals Co., Ltd.)).

The configuration of the resin film substrate forming the release film and the configuration of the paper substrate forming the release paper are not especially limited. As the resin film substrate, a resin film such as a polyester-based resin, a polyethylene-based resin, a polystyrene-based resin, a polypropylene-based resin, a nylon-based resin, a urethane-based resin, a polyvinylidene chloride-based resin, or a polyvinyl chloride-based resin is used. A polyester-based resin, such as polyethylene terephthalate (PET) or polyethylene naphthalate (PEN), is preferred, and PET is particularly preferred. As the paper substrate, general paper materials are applicable.

In the surface plate of the present invention, the release layer is formed by fixing the release film or the release paper on the surface plate body. The thickness of the release film or the release paper is not especially limited, and is preferably 50 μm or more and 500 μm or less. The release film or the release paper is preferably rigidly fixed on the surface plate body with a pressure-sensitive adhesive or an adhesive agent. Examples of the pressure-sensitive adhesive and the adhesive agent used for this purpose include acryl-based or rubber-based pressure-sensitive adhesives, and silicone-based and epoxy-based pressure-sensitive adhesives and adhesives.

To the release layer including the release film or the release paper described above, a surface plate basically the same as a conventional one is applied. A surface plate provided with an unusual configuration hinders the use of the present invention. In a polishing apparatus, the surface plate is a member that holds a polishing pad and is rotatively driven to polish a work.

Further, the surface plate is not limited to one having a single structure. There is a known surface plate separated into a plurality of members having a member for fixing a polishing pad thereon, a member connected to mechanical means of a polishing apparatus for rotatively driving the surface plate, and the like. In the present invention, a member for fixing a polishing pad thereon is defined as the surface plate body regardless of the shape and the size.

The surface plate body on which a polishing pad is to be fixed preferably includes a material that is hard and excellent in corrosion resistance, and specifically, preferably includes stainless steel, cast iron, or ceramics such as SiC.

Further, a surface roughness of the surface of the surface plate body on which the release layer (release film or the release paper) is to be fixed is preferably 0.01 μm or more and 2.0 μm or less in terms of arithmetic average roughness (Ra). When the surface roughness of the surface plate body is over 2.0 μm, a fixed state of the release film or the release paper used as the release layer becomes slightly unstable, which may cause a shift of a polishing pad to deteriorate polishing accuracy. The surface roughness of the surface plate body is preferably reduced as much as possible, and from a realistic point of view, a lower limit is 0.01 μm. As the surface roughness herein, an average of in-plane surface roughnesses of the surface plate is preferably employed, and an average of measured values of the surface roughness at two or more portions, such as a central portion and an end portion (outer peripheral portion), of the surface plate is preferably defined as the surface roughness of the surface plate.

### (II) Polishing Apparatus provided with Surface Plate of Present Invention

The surface plate of the present invention described above can be connected to a conventional polishing apparatus to perform polishing work. A polishing apparatus including the surface plate of the present invention is a polishing apparatus having good efficiency in replacement work including detachment/attachment of a polishing pad.

Polishing apparatuses include a one-surface polishing apparatus (exemplarily illustrated in FIG. 1) for polishing one surface of a work with a polishing pad attached to one surface plate, and a both-surface polishing apparatus (exemplarily illustrated in FIG. 3) for polishing both surfaces of a work with polishing pads respectively attached to two (a pair of) surface plates (an upper surface plate and a lower surface plate). The surface plate of the present invention is applicable to both the one-surface polishing apparatus and the both-surface polishing apparatus. When the present invention is applied to the both-surface polishing apparatus, the present invention can be applied to either one of the surface plates, and the present invention is preferably applied to both the surface plates. When the present invention is applied to both the surface plates of the both-surface polishing apparatus, the peel forces of the release layers of the both surface plates can be equivalent. Alternatively, in consideration that the lower surface plate of the both-surface polishing apparatus receives the load of the upper surface plate, the release layers of the lower surface plate and the upper surface plate can be set to have different peel forces.

### (III) Polishing Method of Present Invention

The release film or the release paper to be used as the release layer of the surface plate of the present invention is available as a single member. Therefore, when the release film or the release paper is fixed on a surface plate body of a conventional surface plate not including a release layer, and a polishing pad is attached thereon, a suitable polishing method can be performed.

Specifically, a polishing method of the present invention is one for polishing a work with a polishing pad attached to a surface plate body, including forming a release layer by fixing, to the surface plate body, a release film or release paper having a peel force of the surface thereof of 0.08 N/50 mm or more and 5.0 N/50 mm or less before attaching the polishing pad, and then polishing the work with the polishing pad attached to the release layer.

In the polishing method of the present invention described above, the release film or the release paper to be fixed on the surface plate body is the same as that described above. A surface of the release film or the release paper preferably includes a silicone-based resin, a fluorine-based resin, a long-chain alkyl-based resin, a paraffin-based resin, or an olefin-based resin. The release film or the release paper is constituted by causing such a resin layer to be supported on a resin film substrate or paper substrate. The resin film substrate or the paper substrate is the same as that described above.

As a fixing method for fixing the release film or the release paper on the surface plate body, it is preferably rigidly fixed on the surface plate body with a pressure-sensitive adhesive or an adhesive agent. As the pressure-sensitive adhesive or the adhesive agent, any of acryl-based or rubber-based pressure-sensitive adhesives, and silicone-based or epoxy-based pressure-sensitive adhesives and adhesive agent are applied.

After fixing the release film or the release paper on the surface plate body, a polishing pad is attached to the surface plate to start polishing work. As the polishing pad, a conventional polishing pad is used. The polishing pad is constituted by applying a pressure-sensitive adhesive or an adhesive agent to a polishing layer (polishing cloth) for polishing a work. The polishing layer includes, for example, a nonwoven fabric formed of nylon, polyurethane, polyethylene terephthalate or a foamed molded product. Examples of the pressure-sensitive adhesive or the adhesive agent applied to the polishing layer include acryl-based or rubber-based pressure-sensitive adhesives, and silicone-based or epoxy-based adhesives.

The polishing method of the present invention aims to improve efficiency of polishing pad replacement work by forming the release layer on the surface of the surface plate. A target is basically a polishing pad including a pressure-sensitive adhesive or an adhesive agent. As the polishing pad, however, a polishing pad provided with an adsorbent including a silicone composition having a specific configuration (Patent Document 1) can be used. The adsorbent including a silicone composition has appropriately strong adsorption power. The release layer formed on the surface plate body in the present invention can also reduce a force for peeling this adsorbent. Accordingly, the polishing pad including the adsorbent including a silicone composition can be effectively used in the present invention.

The adsorbent including a silicone composition is formed by stacking a composition obtained by crosslinking at least one silicone selected from a silicone including linear polyorganosiloxane having vinyl groups only at both ends, a silicone including linear polyorganosiloxane having vinyl groups at both ends and side chains, a silicone including branched polyorganosiloxane having vinyl groups only at ends, and a silicone including branched polyorganosiloxane having vinyl groups at ends and side chains.

As specific examples of the silicones, examples of the linear polyorganosiloxane include compounds of Chemical Formula 1. An example of the branched polyorganosiloxane includes a compound of Chemical Formula 2.

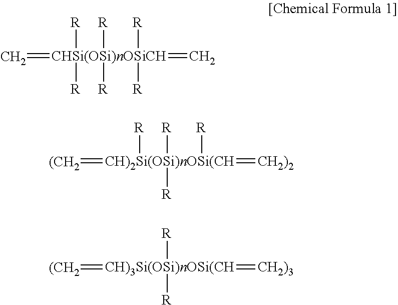

(R represents an organic group as described below, and n represents an integer).

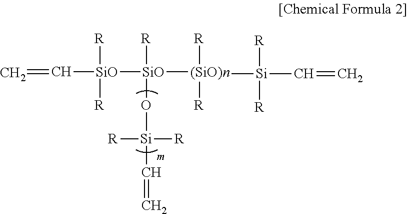

(R represents an organic group as described below, and m and n each represent an integer).

Specific examples of the substituent (R) in Chemical Formulae 1 and 2 include alkyl groups such as a methyl group, an ethyl group and a propyl group; aryl groups such as a phenyl group and a tolyl group; and monovalent hydrocarbon groups in which some or all of hydrogen atoms bonded to the above-mentioned alkyl group or aryl group are substituted with halogen atoms, cyano groups or the like, excluding homologous or heterologous unsubstituted or substituted aliphatic unsaturated groups. The polyorganosiloxane is preferably one including methyl groups in an amount of 50 mol %. The substituents may be heterologous or homologous. The polysiloxane may be a single polysiloxane or a mixture of two or more polysiloxanes.

Further, the silicone that forms the adsorbent has a preferred adsorption effect when the silicone has a number average molecular weight of 30000 to 100000. The number average molecular weight of the silicone is preferably 30000 to 60000.

After fixing the polishing pad on the surface plate body via the release layer, a work is polished by a usual method. Since the present invention is applicable to both one-surface polishing and both-surface polishing, the release film or the release paper is fixed and a polishing pad is fixed on each of the surface plates in performing the both-surface polishing. In accordance with progress of polishing work, the polishing pad is replaced if necessary. At this point, owing to the release layer of the surface plate, polishing pad effect work can be smoothly performed.

### ADVANTAGEOUS EFFECTS OF THE INVENTION

According to the surface plate for a polishing apparatus and the polishing method of the present invention described above, pad replacement work can be easily performed in a polishing step in which a conventionally widely used polishing pad using a pressure-sensitive adhesive is used. The surface plate of the present invention is the same in the basic configuration as a conventional surface plate, and can exhibit the above-described effect without deteriorating polish quality.

### BRIEF DESCRIPTION OF THE DRAWINGS

FIG. 1 is a diagram roughly illustrating a polishing apparatus and a polishing step performed with a polishing pad.

FIG. 2 is a diagram illustrating an exemplified configuration of a surface plate included in a polishing apparatus (one-surface polishing apparatus) of First Embodiment.

FIG. 3 is a diagram roughly illustrating a configuration of a polishing apparatus (both-surface polishing apparatus) of Second Embodiment.

### DESCRIPTION OF EMBODIMENTS

First Embodiment: Hereinafter a preferred embodiment of the present invention will be described. In the present embodiment, a surface plate to which a release film is bonded was produced, a commercially available polishing pad equipped with a pressure-sensitive adhesive was fixed on the surface plate in a one-surface polishing apparatus to perform polishing work, and thus, workability in replacement was examined and polish quality was evaluated.

The polishing pad used in the present embodiment was a commercially available circular polishing pad including a general-purpose suede type polishing cloth (model: 7355-000F, nap length: 450 μm, thickness: 1.37 mm). In the polishing pad, a pressure-sensitive adhesive tape was attached to the back surface.

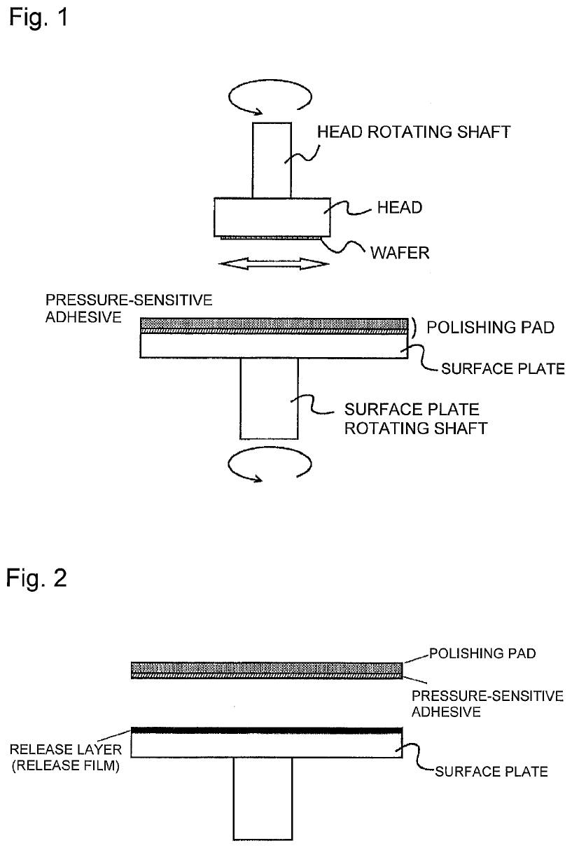

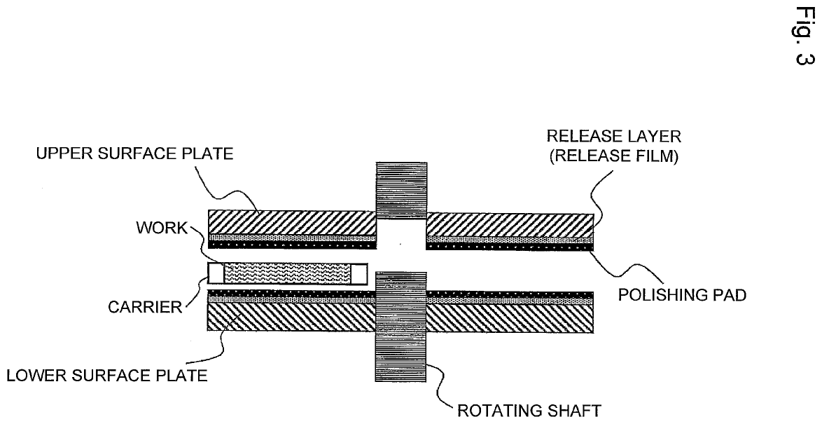

Then, in a one-surface polishing apparatus similar to the apparatus illustrated in FIG. 1, a release film was bonded to a main body portion of a surface plate as illustrated in FIG. 2 to produce a surface plate according to the present embodiment. In the present embodiment, a plurality of types of commercially available silicone-based release films (manufactured by Fujico Co., Ltd.: product name: PET-75x1 (thickness: 75 μm)) having different peel forces were prepared to produce a plurality of surface plates, and properties of the release layers were evaluated. In the present embodiment, release films respectively having a peel force of 0.05 N/50 mm, 0.08 N/50 mm, 0.2 N150 mm, 0.95 N/50 mm, 5.0 N/50 mm, and 7.0 N/50 mm were prepared. Each of these release films was cut into the same size (ϕ800 mm) as that of the surface plate, and the resultant was adhesively bonded with an acryl-based adhesive.

The polishing apparatus and the polishing pads prepared as described above were used to conduct a polishing test with a silicon wafer (ϕ8 inches) used as a work (member to be polished). In this polishing test, the release film was adhesively fixed on the surface plate with a pressure-sensitive adhesive, and then the polishing pad was adhesively fixed on the release film to polish the silicon wafer. In this polishing test, while a polishing slurry is being supplied dropwise to the polishing pad, the polishing pad (surface plate) and the silicon wafer (head) were rotated to polish the silicon wafer. Polishing conditions employed here were as follows:
Polishing slurry: slurry obtained by diluting Glanzox (manufactured by Fujimi Inc.) with pure water by 30 times
Dripping speed of polishing slurry: 150 ml/min
Polishing pressure: 0.163 kgf/cm²
Rotation speed of polishing pad: 45 rpm
Rotation speed of head: 47 rpm
Oscillation speed of head: 250 mm/min
Polishing time: 3 min (per wafer)

In the polishing test of the present embodiment, after twenty-five silicon wafers were continuously polished under the above-described conditions, the polishing pad was separated by pulling from the surface plate (release film), a new polishing pad was adhesively fixed, and then, twenty-five silicon wafers were similarly continuously polished. In the present embodiment, two hundred silicon wafers in total were polished, and the polishing pad replacement work (separating work) was performed seven times. Each silicon wafer obtained after the polishing work was washed with pure water and dried, and the weight was measured with a micro-electronic balance to evaluate a polishing rate based on a weight difference caused by the polishing.

As an evaluation method employed in the polishing test, the fixed state (adhesion state) between a polishing pad and a surface plate was visually and tactilely checked in all the polishing work performed with the respective release films to examine whether or not the polishing pad was shifted or peeled. When a shift or the like of the polishing pad was found, the corresponding release film was determined to fail, and the test was abandoned.

In addition, working efficiency in the polishing pad replacement work performed seven times was also evaluated. In the present embodiment, a spring balance was used, in the replacement work, to pull an end portion of the polishing pad upward at 90 degrees, and a load applied when the polishing pad was peeled was thus measured. When the load value was 500 g or less, the working efficiency was determined as good “O”, and when the load value was over 500 g, the working efficiency was determined as poor “x”. For the evaluation of the load value, an average of measured values obtained in the replacement work performed seven times was used.

The aforementioned polishing test and evaluation were conducted on the surface plates on which the prepared seven types of release films having different peel forces were respectively fixed. Further, in the present embodiment, two types, that is, acryl-based and rubber-based, pressure-sensitive adhesives were prepared, and the polishing test was conducted with a release film fixed on the surface plate with each of the pressure-sensitive adhesives. In addition, in the present embodiment, the polishing test was conducted with a polishing pad directly adhesively fixed on a surface plate as a conventional example. Evaluation results obtained in the polishing test described above are shown in Table 1.

TABLE 1

| Release | Surface | Occurrence of | Evaluation of | |
|---|---|---|---|---|
| Film | Plate | Shift/Peel in | Replacement | Polishing |
| Peel Force | Fixing | Polishing | Efficiency | Rate |
| (N/50 mm) | Method | Work | (Peel Load) | (μm/min) |
| 0.05 | Rubber- | Shifted | — | 0.04 |
| | based | (13th pad) | | |
| | Acryl- | Shifted | — | |
| | based | (7th pad) | | |
| 0.08 | Rubber- | Not | ∘ | 0.1 |
| | based | shifted/peeled | (93 g) | |
| | Acryl- | Not | ∘ | |
| | based | shifted/peeled | (40 g) | |
| 0.2 | Rubber- | Not | ∘ | 0.09 |
| | based | shifted/peeled | (175 g) | |
| | Acryl- | Not | ∘ | |
| | based | shifted/peeled | (86 g) | |
| 0.95 | Rubber- | Not | ∘ | 0.1 |
| | based | shifted/peeled | (359 g) | |
| | Acryl- | Not | ∘ | |
| | based | shifted/peeled | (297 g) | |
| 5.0 | Rubber- | Not | ∘ | 0.1 |
| | based | shifted/peeled | (483 g) | |
| | Acryl- | Not | ∘ | |
| | based | shifted/peeled | (457 g) | |
| 7.0 | Rubber- | Not | x | 0.09 |
| | based | shifted/peeled | (over 500 g) | |
| | Acryl- | Not | x | |
| | based | shifted/peeled | (over 500 g) | |
| — (directly | Rubber- | Not | x | 0.09 |
| fixed) | based | shifted/peeled | (over 500 g) | |

Table 1 shows that the polishing pad was neither shifted nor peeled during the polishing work and a good polishing state was obtained when the peel force of the release layer (release film) of the surface plate was 0.08 N/50 mm or more and 5.00 N/50 mm or less. Further, the peel load in the polishing pad replacement was 500 g or less in such a surface plate, and it was thus confirmed that such a surface plate is also excellent in efficiency in the replacement. It was also confirmed that the polishing work with a polishing rate equivalent to that of the conventional example can be performed in using such a surface plate.

On the other hand, when the peel force of the release layer of the surface plate was over 5.0 N/50 mm (7.0 N/50 mm), the peel load in the polishing pad replacement was over 500 g, and it was thus confirmed that such a surface plate is poor in efficiency in the replacement. In this comparative example, the polishing pad was not shifted, and the polishing rate was good, which can be the same as those in the conventional example in which the polishing pad was directly fixed on the surface plate.

When the peel force of the release layer of the surface plate was less than 0.08 N/50 mm (0.05 N/50 mm), the polishing pad was shifted during the polishing work. This problem occurred during the polishing of the first twenty-five silicon wafers, and hence the test was abandoned without performing the first replacement work. In this surface plate, the polishing rate was lower by 0.05 μm/min than that of the conventional example. It is presumed that this failure of the polishing rate was caused because the polishing pad was in an unpreferable fixed state. It is thus understood that reduction of the peel force of the surface of a surface plate also affects the polish quality.

Second Embodiment: In the present embodiment, a release layer was formed on both an upper surface plate and a lower surface plate of a both-surface polishing apparatus to perform polishing work, and thus, stability of polishing pad fixation was evaluated.

FIG. 2 is a diagram roughly illustrating the configuration of the both-surface polishing apparatus used in the present embodiment. The both-surface polishing apparatus of FIG. 2 includes an upper surface plate, a lower surface plate, a rotating shaft for rotatively driving these surface plates. In polishing work with the both-surface polishing apparatus, a polishing pad is attached and fixed on each of the surface plates, and a work (member to be polished) fixed with a carrier is inserted between the surface plates to perform polishing. Gears are formed on outer peripheries of the carrier and the rotating shaft, so that the carrier can be also rotatively driven by driving the rotating shaft.

In the present embodiment, a release film used as a release layer was attached to a main body portion of each of the upper surface plate and the lower surface plate to produce a surface plate of the present embodiment. The release film was a silicone-based release film (manufactured by Fujico Co., Ltd.: product name: PET-75x1 (thickness: 75 μm)), and had a peel force of 0.2 /50 mm. A polishing pad was fixed to the surface of the release layer. The polishing pad used in the present embodiment was a general-purpose urethane type (CeO₂) circular (donut-shaped) polishing pad, and an acryl-based pressure-sensitive adhesive tape was attached to the back surface. As the size of the surface plates, both the upper and lower surface plates had a fixing surface of ϕ680 mm, and the polishing pad had an outer diameter of the same size.

Then, the polishing apparatus and the polishing pad described above were used to conduct a polishing test with a glass wafer (ϕ8 inches) used as a work. In this polishing test, the polishing pads were adhesively fixed on the surface plates having the release films adhesively fixed thereon to polish the silicon wafer. In the polishing step, the silicon wafer was polished by rotating the upper and lower polishing pads and the silicon wafer while a polishing slurry was being supplied through a large number of supply ports (not shown) provided on the upper surface plate. Polishing conditions employed here were as follows:
Polishing slurry: SHOREX FL-2 (manufactured by Showa Denko K.K.)
Amount of polishing slurry supplied: 5 l/min
Polishing pressure: 0.48 Kgf/cm²
Rotation speed of surface plates: 40 rpm for upper and lower plates

In the polishing test of the present embodiment, the polishing was performed for 80 hours under the above-described conditions, and the polishing work was stopped after the polishing of 5 hours, 10 hours, 20 hours, and 40 hours to measure peel forces of the polishing pads against the upper and lower surface plates. In the present embodiment, a tension load cell equipped with a hook was hooked on an end portion of the polishing pad to pull it upward at 90 degrees, and a load applied when the polishing pad was peeled was defined as the peel force. For this measurement, a loop to be hooked was attached to a part of the outer periphery of the polishing pad. After measuring the peel force, the polishing pads were attached to the surface plates again to continue the polishing work. The measurement of the peel force and the polishing work were thus repeated, and the polishing was performed until 80 hours elapsed. Measurement results obtained in this evaluation test are shown in Table 2.

TABLE 2

| | Polishing Pad Peel Force (kg) | | | | |
|---|---|---|---|---|---|
| | 5 hours | 10 hours | 20 hours | 40 hours | 80 hours |
| Upper Surface | 3.3 | 3.2 | 3.5 | 4.3 | 4.2 |
| Plate | | | | | |
| Lower Surface | 3.1 | 3.5 | 3.8 | 4.1 | 4.3 |
| Plate | | | | | |

It can be confirmed, based on Table 2, that the peel forces of the polishing pads measured after elapse of the respective times are stable in the surface plate including the peel layer of the present embodiment. According to the surface plate of the present embodiment, a work can be polished without peeling or shifting a polishing pad during the polishing work performed for 80 hours. In this polishing test, it is probably because of accumulation of pressing time that the peel force of the polishing pad increased as the polishing time was increased. When the polishing pad was separated from the surface plate after the polishing test, however, the polishing pad could be detached/attached without special difficulty, and no adhesive remained on the surface of the surface plate.

As described so far, it was confirmed that when a peel layer of a surface plate is provided with a proper peel force, stable polishing can be performed during polishing work, and that a polishing pad can be easily detached/attached after the work. When the surface of the work was observed after the polishing test, a good polished surface having neither a polishing scratch nor waviness/distortion was obtained.

### INDUSTRIAL APPLICABILITY

As described above, since a surface plate for a polishing apparatus according to the present invention includes a release layer including a release film or the like, workability for fixing/replacing a polishing pad to be fixed with a pressure-sensitive adhesive is improved. The present invention is useful in a polishing step for a semiconductor wafer, a glass substrate for a display or a substrate for a hard disc.

1. A surface plate for a polishing apparatus, to be used in a polishing apparatus, with a polishing pad attached on the surface plate, comprising:
a surface plate body; and a release layer including a release film or release paper formed on a surface of the surface plate body on which the polishing pad is to be attached,
wherein the release layer has a peel force of a surface thereof of 0.08 N/50 mm or more and 5.0 N/50 mm or less.

2. The surface plate for a polishing apparatus according to claim 1, wherein the surface of the release layer includes a silicone-based resin, a fluorine-based resin, a long-chain alkyl-based resin, a paraffin-based resin, or an olefin-based resin.

3. The surface plate for a polishing apparatus according to claim 1, wherein the surface plate body includes stainless steel, cast iron, or ceramics.

4. The surface plate for a polishing apparatus according to claim 1, wherein the surface of the surface plate body on which the release layer is formed has a surface roughness, in terms of arithmetic average roughness (Ra), of 0.1 μm or more and 2.0 μm or less.

5. A polishing apparatus, comprising the surface plate defined in claim 1.

6. A polishing method for polishing a work with a polishing pad attached to a surface plate body, comprising:
forming a release layer by fixing, to the surface plate body, a release film or release paper having a peel force of a surface thereof of 0.08 N/50 mm or more and 5.0 N/50 mm or less before attaching the polishing pad; and then
polishing the work with the polishing pad attached to the release layer.

7. The polishing method according to claim 6, wherein the surface of the release film or the release paper includes a silicone-based resin, a fluorine-based resin, a long-chain alkyl-based resin, a paraffin-based resin, or an olefin-based resin.

8. The polishing method according to claim 6, wherein the polishing pad is constituted by applying a pressure-sensitive adhesive or an adhesive agent to a polishing layer.

9. The polishing method according to claim 6,
wherein the polishing pad is constituted by stacking an adsorbent on a polishing layer, and
the adsorbent includes a silicone composition obtained by crosslinking at least one silicone selected from a silicone including linear polyorganosiloxane having vinyl groups only at both ends, a silicone including linear polyorganosiloxane having vinyl groups at both ends and side chains, a silicone including branched polyorganosiloxane having vinyl groups only at ends, and a silicone including branched polyorganosiloxane having vinyl groups at ends and side chains.

10. The surface plate for a polishing apparatus according to claim 2, wherein the surface plate body includes stainless steel, cast iron, or ceramics.

11. The surface plate for a polishing apparatus according to claim 2, wherein the surface of the surface plate body on which the release layer is formed has a surface roughness, in terms of arithmetic average roughness (Ra), of 0.1 μm or more and 2.0 μm or less.

12. The surface plate for a polishing apparatus according to claim 3, wherein the surface of the surface plate body on which the release layer is formed has a surface roughness, in terms of arithmetic average roughness (Ra), of 0.1 μm or more and 2.0 μm or less.

13. A polishing apparatus, comprising the surface plate defined in claim 2.

14. A polishing apparatus, comprising the surface plate defined in claim 3.

15. A polishing apparatus, comprising the surface plate defined in claim 4.

16. The polishing method according to claim 7, wherein the polishing pad is constituted by applying a pressure-sensitive adhesive or an adhesive agent to a polishing layer.

17. The polishing method according to claim 7,
wherein the polishing pad is constituted by stacking an adsorbent on a polishing layer, and
the adsorbent includes a silicone composition obtained by crosslinking at least one silicone selected from a silicone including linear polyorganosiloxane having vinyl groups only at both ends, a silicone including linear polyorganosiloxane having vinyl groups at both ends and side chains, a silicone including branched polyorganosiloxane having vinyl groups only at ends, and a silicone including branched polyorganosiloxane having vinyl groups at ends and side chains.
